(19) United States
(12) Patent Application Publication
(10) Pub. No.: US 2024/0145241 A1
(43) Pub. Date: May 2, 2024

(54) SURFACE MODIFIERS FOR ENHANCED EPITAXIAL NUCLEATION AND WETTING

(71) Applicant: Applied Materials, Inc., Santa Clara, CA (US)

(72) Inventors: Joe MARGETIS, Gilbert, AZ (US); John TOLLE, Gilbert, AZ (US); Shawn THOMAS, Chesterfield, MO (US)

(21) Appl. No.: 18/383,100

(22) Filed: Oct. 24, 2023

Related U.S. Application Data
(60) Provisional application No. 63/419,525, filed on Oct. 26, 2022.

(51) Int. Cl. H01L 21/02; H01L 21/3065

(52) U.S. Cl. CPC H01L 21/02639; H01L 21/02532; H01L 21/02576; H01L 21/3065

(57) ABSTRACT

Method of forming a semiconductor device are provided. In some implementations, the method includes positioning a substrate into a processing chamber, the substrate having an exposed non-crystalline surface and an exposed crystalline surface. The method further includes heating the processing chamber to a temperature for deposition. The method further includes injecting a pre-treatment gas into the processing chamber. The pre-treatment gas comprises a molecule that acts to lower interfacial energy between the exposed non-crystalline surface and the exposed crystalline surface. The method further includes injecting a deposition gas into the processing chamber to selectively grow an n-type doped epitaxial silicon layer on the exposed crystalline surface.

### CROSS-REFERENCE TO RELATED APPLICATIONS

This application claims priority to U.S. Provisional Patent Application Ser. No. 63/419,525, filed on Oct. 26, 2022, which is herein incorporated by reference in its entirety.

### BACKGROUND

### Field

Embodiments of the present disclosure generally relate to a method for forming a semiconductor device. More specifically, the application relates to epitaxial deposition methods for forming horizontal gate-all-around (hGAA) device structures.

### Description of the Related Art

The electronics industry is experiencing an ever-increasing demand for smaller and faster electronic devices, which are simultaneously able to support a greater number of increasingly complex and sophisticated functions. Accordingly, there is a continuing trend in the semiconductor industry to manufacture low-cost, high-performance, and low-power integrated circuits (ICs). These goals have been achieved in large part by scaling down semiconductor IC dimensions (e.g., minimum feature size) and thus improving production efficiency and lowering associated costs. However, such miniaturization has introduced greater complexity into the semiconductor manufacturing process. Thus, the realization of continued advances in semiconductor ICs and devices calls for similar advances in semiconductor manufacturing processes and technology.

Recently, multi-gate devices have been introduced in an effort to improve gate control by increasing gate-channel coupling, reduce OFF-state current, and reduce short-channel effects (SCEs). One such multi-gate device is the gate-all-around transistor (GAA). In a GAA device, all side surfaces of the channel region are surrounded by the gate electrode, which allows for fuller depletion in the channel region and results in less short-channel effects due to a steeper sub-threshold current swing and smaller drain induced barrier lowering (DIBL).

As transistor dimensions are scaled down to smaller technology nodes, there is a need for further improvements in GAA design and manufacturing.

### SUMMARY

Embodiments of the present disclosure generally relate to a method for forming a semiconductor device. More specifically, the application relates to epitaxial deposition methods for forming horizontal gate-all-around (hGAA) device structures.

In at least one aspect, a method of forming a semiconductor device is provided. The method includes positioning a substrate into a processing chamber, the substrate having an exposed non-crystalline surface and an exposed crystalline surface. The method further includes heating the processing chamber to a temperature for deposition. The method further includes injecting a pre-treatment gas into the processing chamber. The pre-treatment gas comprises a molecule configured to lower interfacial energy between the exposed non-crystalline surface and the exposed crystalline surface. The method further includes injecting a deposition gas into the processing chamber to selectively grow an n-type doped epitaxial silicon layer on the exposed crystalline surface.

Embodiments may include one or more of the following. The molecule is a group-V chloride. The molecule is selected from a group consisting of PCl₃, AsCl₃, and SbCl₃. The injecting a pre-treatment gas and the injecting a deposition gas at least partially overlap. The injecting a pre-treatment gas is completed prior to the injecting a deposition gas. The injecting a pre-treatment gas and the injecting a deposition gas are repeated sequentially a plurality of times. The method further includes exposing the substrate to a dry etchant to remove contaminants from a surface of the substrate. The exposed non-crystalline surface comprises a silicon oxide, a silicon nitride, a silicon carbonitride, a silicon oxycarbide, a silicon oxycarbonitride, or a combination thereof. The dry etching comprises exposure of the substrate to H₂, NF₃, NH₃ and plasma by-products. The plurality of exposed silicon layers have <110> structure. The temperature for deposition is 400 degrees Celsius or higher. The injecting a pre-treatment gas is performed at a pressure within a range from about 1 torr to about 760 torr.

In another aspect, a method of forming a semiconductor device is provided. The method includes positioning a substrate into a processing chamber. The substrate having a multi-material layer formed thereon, the multi-material layer comprising, a plurality of exposed dielectric surfaces on a plurality of Si₁₋ₓGeₓ layers and a plurality of exposed silicon layers. The method further includes heating the processing chamber to a temperature for deposition. The method further includes injecting a pre-treatment gas into the processing chamber, wherein the pre-treatment gas comprises a molecule configured to lower interfacial energy between the plurality of exposed dielectric surfaces and the plurality of exposed silicon layers. The method further includes injecting a deposition gas into the processing chamber to selectively grow an n-type doped epitaxial silicon layer on the exposed silicon layers.

Embodiments may include one or more of the following. The exposed dielectric surface comprises a silicon oxide, a silicon nitride, a silicon carbonitride, a silicon oxycarbide, a silicon oxycarbonitride, or a combination thereof. The molecule is a group-V chloride. The molecule is selected from a group consisting of PCl₃, AsCl₃, and SbCl₃. The injecting a pre-treatment gas and the injecting a deposition gas at least partially overlap.

In yet another aspect, a method of forming a semiconductor device is provided. The method includes positioning a substrate into a cleaning chamber, the substrate having a multi-material layer formed thereon, the multi-material layer comprising a plurality of dielectric surfaces disposed on outer surfaces of a plurality of Si₁₋ₓGeₓ layers and a plurality of silicon layers, the plurality of Si₁₋ₓGeₓ layers arranged in an alternating pattern with the plurality of silicon layers. The method further includes exposing the substrate to a dry etchant to remove contaminants from a surface of the substrate. The method further includes positioning the substrate into a processing chamber. The method further includes heating the processing chamber to a temperature for deposition. The method further includes injecting a pre-treatment gas into the processing chamber, wherein the pre-treatment gas comprises a molecule configured to lower interfacial energy between the dielectric surface and the silicon surface. The method further includes injecting a deposition gas into the processing chamber to selectively grow an n-type doped epitaxial silicon layer on the exposed silicon surface.

Embodiments may include one or more of the following. The molecule is a group-V chloride. The injecting a pre-treatment gas and the injecting a deposition gas are repeated sequentially a plurality of times. The exposed dielectric surface comprises a silicon oxide, a silicon nitride, a silicon carbonitride, a silicon oxycarbide, a silicon oxycarbonitride, or a combination thereof.

In another aspect, a non-transitory computer readable medium has stored thereon instructions, which, when executed by a processor, causes the process to perform operations of the above apparatus and/or method.

### BRIEF DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a schematic isometric view of a horizontal gate-all-around (hGAA) structure, according to one embodiment of the present disclosure.

FIGS. 2A-2C illustrate schematic cross-sectional views of various stages of forming the hGAA structure of FIG. 1, according to one embodiment of the present disclosure.

FIG. 3 illustrates a flow chart of a method of forming a semiconductor device, according to one embodiment of the present disclosure.

FIG. 4 illustrates a schematic side cross-sectional view of an exemplary process chamber, according to one embodiment of the present disclosure.

FIG. 5 illustrates a schematic top view of a system for processing substrates, according to one embodiment of the present disclosure.

### DETAILED DESCRIPTION

Embodiments of the present disclosure generally relate to a method for forming a semiconductor device. More specifically, the application relates to epitaxial deposition methods for forming horizontal gate-all-around (hGAA) device structures.

As the feature sizes of transistor devices continue to shrink to achieve greater circuit density and higher performance, there is a need to improve transistor device structure to improve electrostatic coupling and reduce negative effects such as parasitic capacitance and off-state leakage. Examples of transistor device structures include a planar structure, a fin field effect transistor (FinFET) structure, and a horizontal gate-all-around (hGAA) structure. The hGAA device structure includes several lattice matched channels suspended in a stacked configuration and connected by source/drain regions.

Epitaxial growth of the epitaxial silicon layers, which form the source/drain materials on nanosheet type architectures is typically initiated on the (110) sidewall silicon surfaces and must grow laterally outward and over neighboring silicon spacers. Under some process conditions, the epitaxial layer is resistant to nucleation on the sidewall silicon surfaces and to overgrowing the spacer. For example, process conditions with excess HCl can act “overselective” to the spacer so that continued filling of the source/drain cavity results in void formation. Current techniques either optimize the process conditions or select a specific silicon precursor to enhance wetting and lateral overgrowth of epitaxial materials. However, these current techniques alter the epitaxial process in order to affect the desire outcome. Alteration of the process to accommodate nucleation and overgrowth can compromise other variables like selectivity, throughput, and layer structure.

In addition, the selective growth of the epitaxial silicon layers introduces challenges associated with jagged growth morphology of the epitaxial silicon layers and degree of growth of the epitaxial silicon layers. Therefore, there is a need for a method to improve the growth morphology of the epitaxial silicon layers and degree of growth of the epitaxial silicon layers.

Described herein are methods of forming epitaxial silicon layers that may be used as, for example, n-channel metal oxide semiconductor (NMOS) or p-channel metal oxide semiconductor (PMOS) epitaxial silicon layers within semiconductor device structures, for example, hGAA device structures. The epitaxial silicon layers may be grown on the hGAA device structures to a shaped structure, such as a diamond-like top structure, to form source/drain regions and source/drain extension regions as needed for hGAA semiconductor devices on a substrate.

The methods described include the use of surface modifiers, which enhance epitaxial nucleation and wetting. Pre-dosing of a growth surface with the surface modifiers can assist in the initial stages of nucleation of the epitaxial layer and later stages of dielectric wetting and overgrowth. The surface modifiers act to lower the interfacial energy between the growing semiconductor and the dielectric surface, such that later overgrowth of the spacer from the silicon channel region is facilitated. The surface modifiers can comprise surfactant molecules. The surface modifiers can be pre-injected into the processing chamber prior to introduction of the deposition gases. The surface modifiers can be pulsed sequentially with the deposition gases. Surface modifiers which can activate the dielectric surface for n-type epi growth include group-V chlorides, t-butyl arsine (TBAs), triethyl antimony (TESb), triethyl arsine (TEAs), plasma ammonia (NH₃), plasma hydrogen (H), and plasma deuterium (D). Examples of suitable group-V chlorides for n-type epi growth include phosphorous chlorides, for example, PCl₃, arsenic chlorides, for example, AsCl₃, and antimony chlorides, for example, SbCl₃. Surface modifiers which can activate the dielectric surface for p-type epi growth include group-V chlorides, triethyl gallium (TEGa), triethyl indium (TEIn), triethyl aluminum (TEAT), plasma ammonia (NH₃), plasma hydrogen (H), and plasma deuterium (D). Examples of suitable group-V chlorides for p-type epi growth include aluminum chlorides, for example, AlCl₃, gallium chlorides, for example, GaCl₃, and indium chlorides, for example, InCl₃.

The surface modifiers can be supplied as a pre-treatment gas. The pre-treatment gas can be injected into a processing chamber and adsorbs on both exposed dielectric surface and exposed silicon surfaces. The dielectric surfaces and the silicon surfaces are chemically altered such that the surfaces are more reactive to the deposition gases, which form the epitaxial layer.

The pre-treatment gas is utilized to continuously etch the epitaxial layer as it is formed and improves the overgrowth of the epitaxial layer as the epitaxial layer is deposited onto a superlattice structure. The epitaxial layer selectively forms only on the crystalline portions of the superlattice structure relative to oxide or non-crystalline surfaces. Under some process conditions, the epitaxial layer is resistant to nucleation on the crystalline layers and overgrows the spacers. For example, process conditions with excessive HCl can act “overselective” to the spacer so that the continued filling of the epitaxial silicon layers cavity results in void formation. With the pre-treatment gas, the growth morphology of the epitaxial layer is less jagged and voids are reduced.

This method of improving the growth morphology of the epitaxial layer does not require alteration of the epitaxial process. Alteration of the process to accommodate nucleation and overgrowth can compromise other process variable like selectivity, throughput, and layer structure. In addition, pre-dosing or sequential dosing allows the growth process parameters to be decoupled from the nucleation and overgrowth concerns.

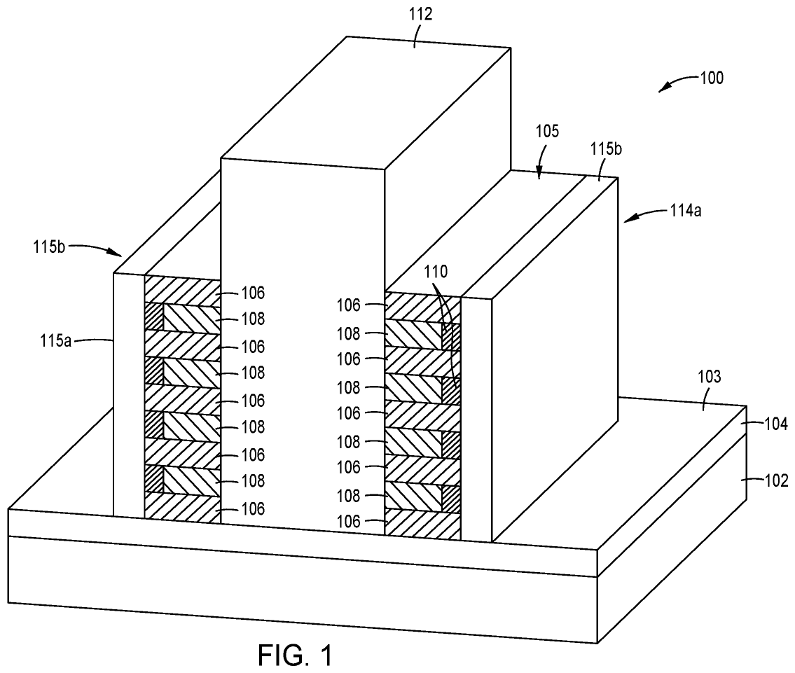

FIG. 1 illustrates a schematic isometric view of an hGAA structure 100, according to one embodiment. The hGAA structure 100 includes a multi-material layer 105 having alternating first layers 106 and second layers 108 with a spacer 110 formed therein utilized in an hGAA structure 100. The hGAA structure 100 utilizes the multi-material layer 105 as nanowires (e.g., channels) between a source 114a, a drain 114b and a gate structure 112. The source/drain 114a, 114b are formed from epitaxial silicon layers 115a, 115b, which are formed according to the method 300. As shown in the cross-sectional view of the multi-material layer 105 in FIG. 1, the spacer 110 formed at the bottom (e.g., or an end) of each of the second layers 108 assists in managing the interface between the second layers 108 and the source/drain 114a, 114b so as to reduce parasitic capacitance and maintain minimum device leakage.

The hGAA structure 100 includes the multi-material layer 105 disposed on a top surface 103 of the substrate 102, such as on top of an optional material layer 104 disposed on the substrate 102. In the embodiments in which the optional material layer 104 is not present, the multi-material layer 105 is directly formed on the substrate 102.

The substrate 102 may be a material such as crystalline silicon (e.g., Si<100> or Si<111>), silicon oxide, strained silicon, silicon germanium, germanium, doped or undoped polysilicon, doped or undoped silicon wafers and patterned or non-patterned wafers silicon on insulator (SOI), carbon doped silicon oxides, silicon nitride, doped silicon, germanium, gallium arsenide, glass, or sapphire. The substrate 102 may have various dimensions, such as 200 mm, 300 mm, 450 mm, or other diameter, as well as, being a rectangular or square panel. Unless otherwise noted, examples described are conducted on substrates with a 200 mm diameter, a 300 mm diameter, or a 450 mm diameter substrate.

In one example, the optional material layer 104 is an insulating material. Suitable examples of the insulating material may include silicon oxide material, silicon nitride material, silicon oxynitride material, or any suitable insulating materials. Alternatively, the optional material layer 104 may be any suitable material including conductive material or non-conductive material as needed. The multi-material layer 105 includes at least one pair of layers, each pair comprising the first layer 106 and the second layer 108. Although the example depicted in FIG. 1 shows four pairs and a first layer 106 cap, each pair includes the first layer 106 and the second layer 108 (alternating pairs, each pair comprising the first layer 106 and the second layer 108). An additional first layer cap 106 is disposed as the top of the multi-material layer 105. The number of pairs may be varied based on different process needs with extra or without extra first layers 106 or second layers 108 being needed. In one embodiment, the thickness of each first layer 106 may be between about 20 Å and about 200 Å, such as about 50 Å, and the thickness of each second layer 108 may be between about 20 Å and about 200 Å, such as about 50 Å. The multi-material layer 105 may have a total thickness between about 10 Å and about 5000 Å, such as between about 40 Å and about 4000 Å.

The first layers 106 are crystalline material layers, such as a single crystalline, polycrystalline, or monocrystalline silicon layer. The first layers 106 are formed using an epitaxial deposition process. Alternatively, the first layers 106 are doped silicon layers, including p-type doped silicon layers or n-type doped layers. Suitable p-type dopants includes B dopants, Al dopants, Ga dopants, In dopants, or the like. Suitable n-type dopant includes N dopants, P dopants, As dopants, Sb dopants, or the like. In yet another example, the first layers 106 are a group III-V material, such as a GaAs layer.

The second layers 108 are non-crystalline material layers. In some embodiments, the second layers 108 are Ge containing layers, such as SiGe layers, Ge layers, or other suitable layers. Alternatively, the second layers 108 are doped silicon layers, including p-type doped silicon layers or n-type doped layers. In yet another example, the second layers 108 are group III-V materials, such as a GaAs layer. In still another example, the first layers 106 are silicon layers and the second layers 108 are a metal material having a high-k material coating on outer surfaces of the metal material. Suitable examples of the high-k material includes hafnium dioxide (HfO₂), zirconium dioxide (ZrO₂), hafnium silicate oxide (HfSiO₄), hafnium aluminum oxide (HfAlO), zirconium silicate oxide (ZrSiO₄), tantalum dioxide (TaO₂), aluminum oxide, aluminum doped hafnium dioxide, bismuth strontium titanium (BST), or platinum zirconium titanium (PZT), among others. In one particular embodiment, the coating layer is a hafnium dioxide (HfO₂) layer. In some embodiments, the second layers 108 are a similar material to the gate structure 112 to form a wraparound gate around the first layers 106.

Each of the spacers 110 are formed adjacent to the ends of the second layers 108 and may be considered a portion of the second layer 108. The spacers 110 are dielectric spacers, air gaps, or a combination of a dielectric spacer and an air gap. The spacers 110 may take any known shape. In some embodiments, the spacers may be crescents, triangles, squares, rectangles, irregular shapes, etc. The spacers 110 may be formed by etching away a portion of each of the second layers 108 using an etching precursor to form a recess at the ends of each of the second layers non-crystalline layer. The spacers 110 are formed in the recesses adjacent each of the second layers 108. A liner layer (not shown) may additionally be deposited within the recesses before the deposition of the spacers 110. The spacers 110 are formed from a dielectric material and separate each of the nanowires or nanosheets formed as the first layer 106. In some embodiments, the spacers 110 are selected to be a silicon containing material that may reduce parasitic capacitance between the gate and source/drain 114a, 114b in the hGAA nanowire structure, such as a low-K material. The silicon containing material or the low-K material may be silicon nitride, silicon oxide, silicon oxynitride, silicon carbide, silicon oxycarbide, silicon carbide nitride, doped silicon layer, or other suitable materials, such as Black Diamond® material available from Applied Materials.

In one embodiment, the spacers 110 are a low-k material (e.g., dielectric constant less than 4) or a silicon oxide/silicon nitride/silicon carbide containing material. In yet other embodiments, the spacers 110 are air gaps.

The gate structure 112 is disposed over and around the multi-material layer 105. The gate structure 112 includes a gate electrode layer and may additionally include a gate dielectric layer, gate spacers, and a mask layer, according to one embodiment. The gate electrode layer of the gate structure 112 includes a polysilicon layer or a metal layer that is capped with a polysilicon layer. The gate electrode layer can include metal nitrides (such as titanium nitride (TiN), tantalum nitride (TaN) or molybdenum nitride (MoNₓ)), metal carbides (such as tantalum carbide (TaC) or hafnium carbide (HfC)), metal-nitride-carbides (such as TaCN), metal oxides (such as molybdenum oxide (MoOₓ)), metal oxynitrides (such as molybdenum oxynitride (MoOₓN_{y})), metal silicides (such as nickel silicide), or combinations thereof. The gate electrode layer is disposed on top of and around the multi-material layer 105.

A gate dielectric layer may optionally be disposed below the gate electrode layer and below the multi-material layer 105. The optional gate dielectric layer can include silicon oxide (SiO₂), which can be formed by a thermal oxidation of one or more of the first layers 106 and/or the second layers 108, or by any suitable deposition process. Suitable materials for forming the gate dielectric layer include silicon oxides, silicon nitrides, oxynitrides, metal oxides such as hafnium oxide (HfO₂), hafnium zirconium oxide (HfZrOₓ), hafnium silicon oxide (HfSiO₂), hafnium titanium oxide (HfTiOₓ), hafnium aluminum oxide (HfAlOₓ), and combinations and multi-layers thereof. Gate spacers are formed on sidewalls of the gate electrode layer. Each gate spacer includes a nitride portion and/or an oxide portion. A mask layer is formed on top of the gate electrode layer and can include silicon nitride.

The composition and formation of the epitaxial silicon layers 115a, 115b, which form the source/drain 114a, 114b on the hGAA structure 100 is described.

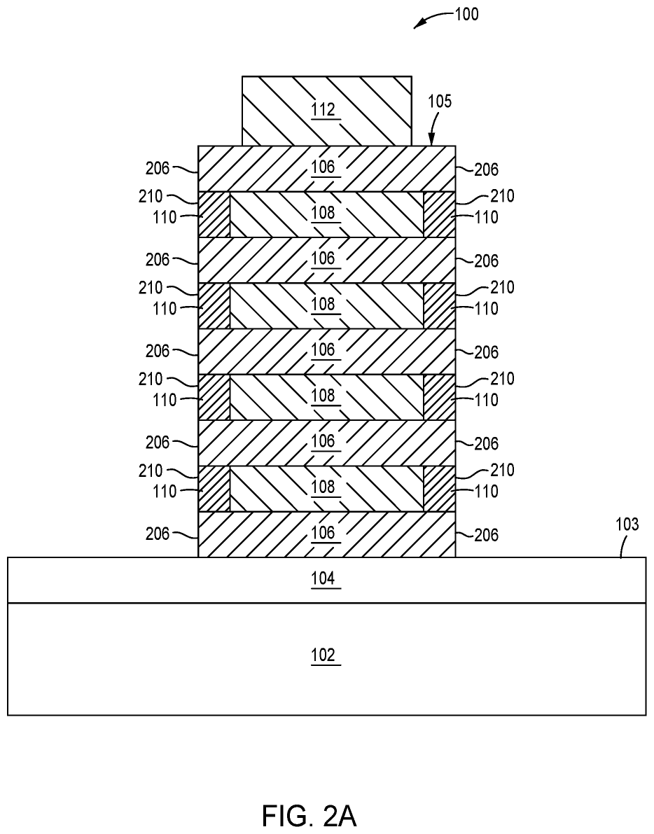

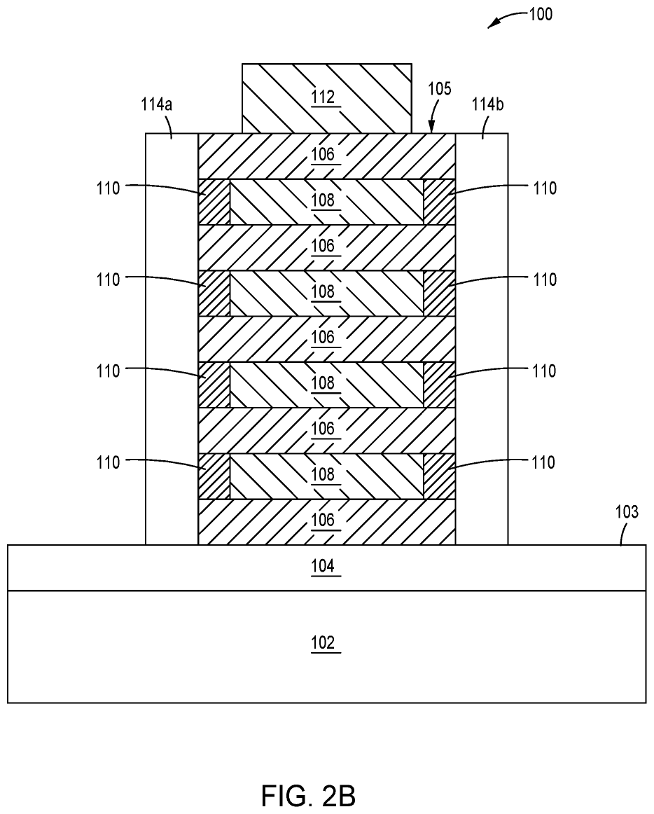

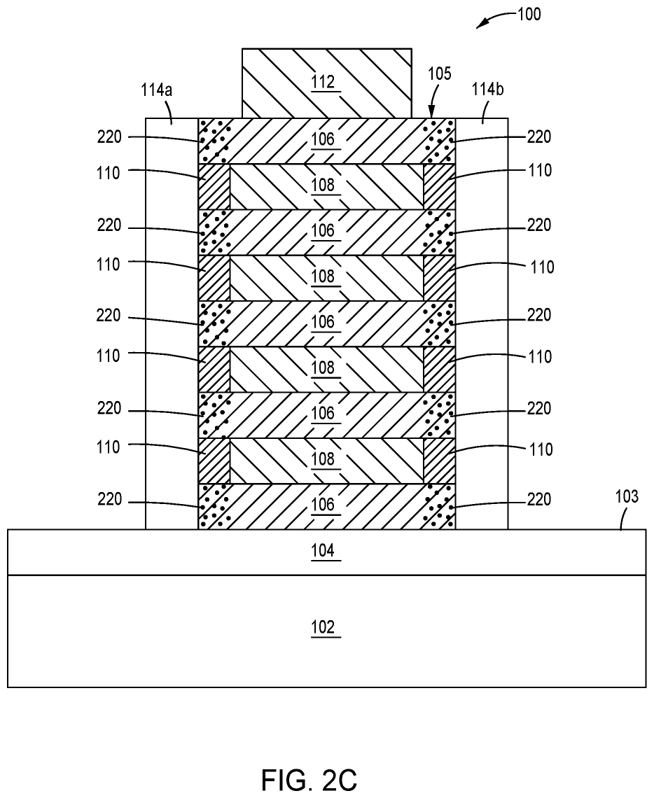

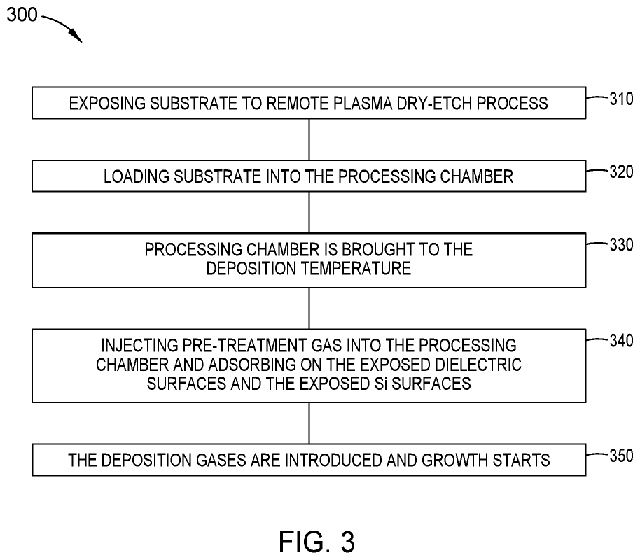

FIGS. 2A-2C are cross-sectional views of a portion of a GAA structure corresponding to various stages of a method 300. FIG. 3 is a flow chart of the method 300 of processing substrates, according to one embodiment. The method 300 may be utilized to form the nanowire structure and the epitaxial silicon layers for horizontal gate-all-around (hGAA) semiconductor device structures on a substrate having desired materials. With reference to FIGS. 2A-2C, cross-sectional views of a gate-all-around structure at various stages of manufacture are provided to illustrate the method of FIG. 3. Although FIGS. 2A-2C are described in relation to the method 300, it will be appreciated that the structure disclosed in FIGS. 2A-2C is not limited to the method 300, but instead may stand alone as a structure independent of the method 300. Similarly, although the method 300 is described in relation to FIGS. 2A-2C, it will be appreciated that the method 300 is not limited to the structures disclosed in FIGS. 2A-2C, but instead may stand alone independent of the structures disclosed in FIGS. 2A-2C.

FIGS. 2A-2C illustrate schematic cross-sectional views of the formation of the hGAA structure 100 of FIG. 1, according to one embodiment. The hGAA structure 100 is formed using the method 300 of FIG. 3. The hGAA structure 100 described is an n-channel metal oxide semiconductor (NMOS) device. Therefore, the dopants within the hGAA structure 100 are n-type dopants, such as phosphorus, arsenic, antimony, or any combination of the above. The dopant includes phosphorus (P), according to one embodiment.

The source/drain 114a, 114b is formed from the epitaxial silicon layers 115a, 115b. The epitaxial silicon layers 115a, 115b may be n-type doped epitaxial silicon layers. The epitaxial silicon layers 115a, 115b may be formed from silicon containing materials, doped silicon materials, compound silicon materials, or non-silicon containing materials. For example, the epitaxial silicon layers 115a, 115b may be silicon, phosphorous-doped silicon, silicon germanium materials, germanium, or other similar materials.

The multi-material layer 105 and the gate structure 112 described with respect to FIG. 2A are formed on the substrate 102 and the optional material layer 104. Prior to starting the method 300, the hGAA structure 100 is similar to the structure in FIG. 2A. The combination of the multi-material layer 105 and the gate structure 112 may be described as a film-stack. The multi-material layer 105 is formed using a plurality of deposition operations to form a plurality of alternating first layers 106 and second layers 108. A portion of the second layer 108 is etched back and the spacers 110 are formed.

The gate structure 112 is formed around the multi-material layer 105. In some embodiments, the gate electrode layer of the gate structure 112 is a similar material to the material of each of the second layers 108 within the multi-material layer 105. The gate structure 112 and the second layers 108 form a wrap-around gate around each of the first layers 106. The first layers 106 act as nanowires or nanosheets disposed within the wrap-around gate. The first layers 106 serve as a channel between epitaxial silicon layers after the formation of the epitaxial silicon layers 115a, 115b, which form the source/drain 114a, 114b.

After the formation of the film-stack, the epitaxial silicon layers 115a, 115b, which form the source/drain 114a, 114b are formed during the method 300 as shown in FIG. 3.

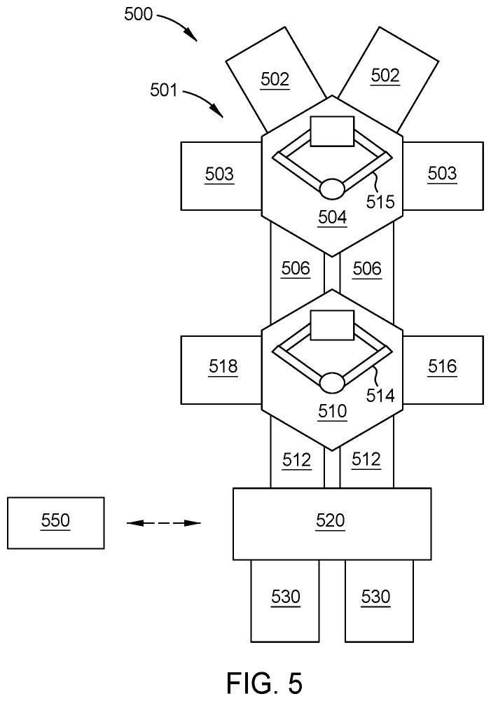

In one embodiment, the method 300 includes an operation 310. Operation 310 includes exposing the substrate to a remote plasma dry-etch process. In one embodiment, operation 310 may be a remote plasma assisted dry etch process, which involves the simultaneous exposure of a substrate to H2, NF3, and NH3 plasma by-products. Remote plasma excitation of the hydrogen and fluorine species allows plasma-damage-free substrate processing. The etch is largely conformal and selective towards silicon oxide layers but does not readily etch silicon regardless of whether the silicon is amorphous, crystalline, or polycrystalline. In one example, the remote plasma dry etch process of operation 310 is a SiCoNi® etch process, which may be performed in a SiCoNi chamber available from Applied Materials, Inc. of Santa Clara, Calif. Operation 310 may be performed in a pre-clean chamber, for example, a cleaning chamber 516 as shown in FIG. 5.

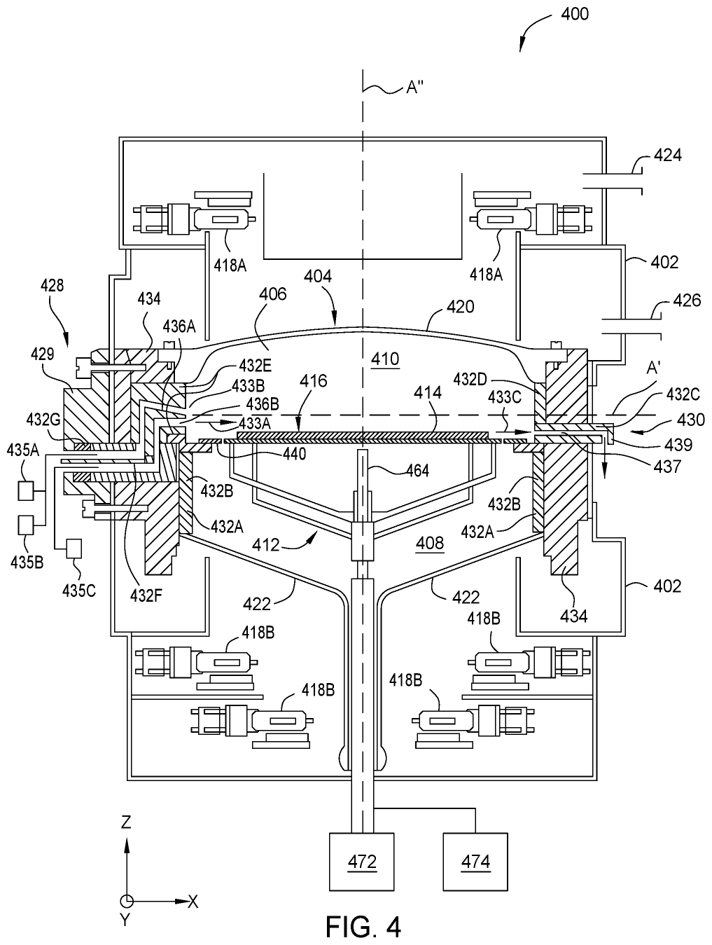

At operation 320, the method 300 includes loading the substrate into a processing chamber. The processing chamber may be an epitaxial deposition chamber, for example, a process chamber 400 as shown in FIG. 4. The process chamber 400 may be positioned on a cluster tool, for example, the cluster tool 501, as a processing chamber, for example, at least one of a plurality of processing chambers 502, 503, 516, 518 as shown in FIG. 5.

At operation 330, the method 300 includes bringing the processing chamber to a deposition temperature. In one embodiment, the deposition temperature may range from 200° C. to 800° C. In another embodiment, the deposition temperature may range from 400° C. to 800° C. In yet another embodiment, the deposition temperature may range from 600° C. to 700° C. In yet another embodiment, the deposition temperature is 400 degrees Celsius or higher. The pressure in the processing chamber may be adjusted so that the reaction region pressure is within range of about 1 torr to about 760 torr, or in a range from about 1 torr to about 600 torr, or in a range from about 100 torr to about 500 torr, or in a range from about 200 torr to about 400 torr.

At operation 340, the method 300 further includes injecting a pre-treatment gas into the processing chamber and adsorption on the exposed dielectric surfaces (e.g., non-crystalline surfaces) and exposed Si surfaces (e.g., crystalline surfaces). In another embodiment, operation 340 includes injecting pre-treatment gas into the processing chamber and adsorption on the exposed non-crystalline surfaces and exposed crystalline surfaces. The pre-treatment gas may be utilized for either n-type epi growth or p-type epi growth. The pretreatment gas includes a molecule or surface modifier configured to lower the interfacial energy between the exposed dielectric surface and the exposed silicon surface, such that overgrowth of the dielectric surface from the silicon surface is facilitated during operation 350. The molecule or surface modifier may also act as an etching agent on the exposed surfaces. In some embodiments, for n-type epi growth, the molecule may be a group-V chloride, t-butyl arsine (TBAs), triethyl antimony (TESb), triethyl arsine (TEAs), plasma ammonia (NH₃), plasma hydrogen (H), and/or plasma deuterium (D). Suit able group-V chlorides for n-type epi growth include phosphorous chlorides, arsenic chlorides, and antimony chlorides. In some embodiments with n-type epi growth, the molecule is PCl₃, AsCl₃, or SbCl₃. In some embodiments, for p-type epi growth, the molecule may be a group-V chloride, triethyl gallium (TEGa), triethyl indium (TEIn), triethyl aluminum (TEAl), plasma ammonia (NH₃), plasma hydrogen (H), and/or plasma deuterium (D). Suitable group-V chlorides for p-type epi growth include gallium chlorides, aluminum chlorides, and indium chlorides. In some embodiments with p-type epi growth, the molecule is GaCl₃, AlCl₃, or InCl₃.

In some embodiments, the pre-treatment gas is accompanied by a carrier gas. Any suitable carrier gas may be used. The carrier gas may be an inert gas. The carrier gas may be selected from H₂, N₂, argon, helium, or a combination thereof.

In some embodiments, the exposed non-crystalline surface (e.g. dielectric surface) comprises silicon oxide (SiO), silicon dioxide (SiO₂), silicon nitride (SiN), silicon carbonitride (SiCN), silicon oxycarbide (SiOC), silicon oxycarbonitride (SiOCN), or a combination thereof.

In one or more embodiments, the silicon carbonitride film has the formula SiC_{y}N_{z}, where y and z are both greater than zero. In one or more embodiments, the silicon oxycarbide film has the formula SiOₓC_{y}, where x and y are both greater than zero. In one or more embodiments, silicon oxycarbonitride has the formula SiOₓC_{y}N_{z} where x, y, and z are all greater than zero. In one or more embodiments, the silicon oxide film has the formula SiOₓ, where x is greater than zero, for example, SiO or SiO₂. In one or more embodiments, the silicon nitride film has the formula SiᵥN_{z}, where v and z are greater than zero, for example, Si₃N₄.

In some embodiments, operation 340 is performed for a time ranging from about 10 seconds to about 120 seconds, or a time ranging from about 10 seconds to about 60 seconds. In other embodiments, operation 340 is performed for a time ranging from about 20 seconds to about 40 seconds. Operation 340 may be operated at a pressure ranging from 200 torr to 400 torr. The flowrate of the pre-treatment gas in operation 340 may range from 1 sccm to about 1000 sccm. In other embodiments, the flowrate of the pre-treatment gas in operation 340 may range from 10 sccm to 100 sccm. The flowrate of the carrier gas during operation 340 may range from about 5 slm to about 30 slm.

During operation 350, a deposition gas mixture is introduced into the process chamber to grow the epitaxial silicon layers 115a, 115b, which form the source/drain 114a, 114b. In at least one implementation, the deposition gas mixture includes a silicon source gas and an n-type dopant. Any suitable silicon source gas may be used. Examples of suitable silicon source gases include silanes and chlorosilanes such as disilane (Si2H6), tetrasilane (Si4H10), trichlorosilane (Cl₃SiH), hexachlorodisilane (Si₂Cl₆), tetrachlorosilane (SiCl₄), pentachlorodisilane (Cl₅Si₂H), octachlorotrisilane (Cl₈Si₃), or a combination thereof. Any suitable n-type dopant may be used. In at least one implementation, the n-type dopant precursor is a phosphorous containing precursor, an antimony precursor, or a combination thereof. Examples of suitable antimony precursors include one or a combination of stibine, antimony trichloride, antimony tetrachloride, antimony pentachloride, triphenylantimony, antimony trihydride, antimonytrioxide, antimony pentoxide, antimony trifluoride, antimony tribromide, antimonytriiodide, antimony pentafluoride, triethyl antimony, and trimethyl antimony. Examples of suitable phosphorous containing precursors include phosphine, trimethylphosphine, dimethylphosphine, triethylphosphine, diethylphosphine, tert-butylphosphine, or a combination thereof. Any suitable p-type dopant may be used. For example, GeH₄, B₂H₆, BCl₃, or a combination thereof.

In some embodiments for n-type deposition, the deposition gas mixture includes DCS/PH₃, TCS/PH₃, DCS/AsH₃, Si₂H₆/PH₃, Si₂H₆/PH₃, Si₄H₁₀/PH₃, or a combination thereof.

In some embodiments for p-type deposition, the deposition gas mixture includes DCS/GeH₄/B₂H₆, SiH₄/GeH₄/B₂H₆, SiH₄/GeH₄/BCl₃, Si₂H₆/GeH₄/B₂H₆, or combinations thereof.

The epitaxial deposition process performed at operation 350 may grow the epitaxial silicon layers 115a, 115b from the first layer 106 of the multi-material layer 105 as shown in FIG. 2B. As the first layer 106 in this example is fabricated from a crystalline material, such as silicon, the epitaxial deposition process of operation 350 may grow from a sidewall 206 of the first layer 106, rather than the spacer 110 (e.g., a silicon dielectric layer).

The epitaxial silicon layers 115a, 115b may then be continuously grown forming a shaped structure, such as a diamond like top structure, to form the source/drain regions and the source/drain extension regions as needed for horizontal gate-all-around (hGAA) semiconductor devices on the substrate 102. As the epitaxial growth process performed at operation 350 may provide a selective deposition process to form the epitaxial silicon layers 115a, 115b predominately atop the sidewall 206 of the first layer 106, which is a silicon material, as well as on the substrate 102 (when the optional material layer 104 is not present), which is also a silicon material, a gap (e.g., a void, a space or an air gap) may be formed dose to a sidewall 210 of the spacer 110. The silicon material is inert to the dielectric materials formed from the spacer 110. Thus, during the epitaxial deposition process, a selective deposition process is achieved to predominantly deposit the epitaxial silicon layers 115a, 115b atop the sidewall 206 of the first layer 106 as the silicon material is mostly inert to the dielectric materials formed from the spacer 110. If present, the gap formed atop of the sidewall 210 of the spacer 110 may later be utilized to form as part of the nanowire spacer (along with the spacer 110) for nanowire structures for horizontal gate-all-around (hGAA) semiconductor devices on a substrate.

The epitaxial silicon layers 115a, 115b, which form the source/drain 114a, 114b, may grow from each of the first layers 106 are deposited on the substrate 102 and each of the first layers 106 within the multi-material layer 205 as shown in FIG. 2B. The epitaxial silicon layers 115a, 115b may have a thickness ranging from about 1 nm to about 10 nm. In embodiments shown, the epitaxial silicon layers 115a, 115b are deposited on the first layers 106 and exposed portions of the substrate 102, which are fabricated from a crystalline material, such as Si, and the epitaxial silicon layers 115a, 115b are not deposited on the gate structure 112 or the spacers 110, which are fabricated from a dielectric material. The pressure in the processing chamber may be adjusted so that the reaction region pressure is within range of about 1 to about 760 Torr, or in a range from about 1 torr to about 600 torr, or in a range from about 100 torr to about 300 torr, or in a range from about 200 torr to about 300 torr. In some embodiments, a carrier gas (e.g., nitrogen) may be flowed into the processing chamber at a flow rate of approximately 1 to 40 SLM (standard liters per minute).

The deposition gas mixture utilized in operation 350 includes a silicon-containing precursor. For example, a chlorosilane precursor. Suitable chlorosilane precursors include dichlorosilane (DCS), trichlorosilane (TCS), or a combination thereof. The silicon-containing precursor may be co-flowed with a dopant gas, for example, an n-type dopant gas or a p-type dopant gas.

The deposition gas mixture utilized in operation 350 may further include a dopant gas, for example, an n-type dopant or a p-type dopant. In some embodiments, the n-type dopants may be phosphorous (P), arsenic (As), antimony (Sb), and in gallium arsenic (GaAs): sulphur (S), selenium (Se), tin (Sn), silicon (Si), and carbon (C). The p-type dopants include but are not limited to boron (B). Exemplary dopant gases may include boron-containing gas such as BH₃ or a phosphorous or arsenic containing gas such PH₃ or AsH₃, wherein the concentration of impurity in the gas phase determines its concentration in the epitaxial silicon layers 115a, 115b. According to an exemplary embodiment, epitaxial silicon layers 115a, 115b are formed from an in-situ doped (i.e. during growth) epitaxial material such as in-situ doped epitaxial Si, carbon doped silicon (Si:C) and/or SiGe. The use of an in-situ doping process in operation 350 is merely an example. For instance, an ex-situ process may be used to introduce dopants into the epitaxial silicon layers 115a, 115b. Other doping techniques may also be utilized to incorporate dopants into the epitaxial silicon layers 115a, 115b. Dopant techniques include but are not limited to, ion implantation, gas phase doping, plasma doping, plasma immersion ion implantation, cluster doping, infusion doping, liquid phase doping, solid phase doping, in-situ epitaxy growth, or any suitable combination of those techniques.

The deposition gas mixture may further include a carrier gas. Any suitable carrier gas may be used. The carrier gas may be an inert gas. For example, the deposition gas may further contain H₂, N₂, argon, helium, or a combination thereof.

In some embodiments, operation 340 and operation 350 completely overlap. In other embodiments, operation 340 and operation 350 partially overlap. In other embodiments, operation 340 and operation 350 do not overlap.

In some embodiments, operation 340 and operation 350 are performed only once. In other embodiments, operation 350 is performed only once, and operation 340 is performed twice—once before operation 350 and a second time after operation 350. In yet other embodiments, operation 340 and operation 350 are performed a plurality of times.

The amount of overgrowth and uniformity in the epitaxial silicon layers 115a, 115b can be controlled by varying processing conditions, such as partial pressure of the pre-treatment gas, ratio of the molecule in the pre-treatment gas, processing temperature, the number of repetitions of operation 340 and operation 350, and/or layer thickness.

In some embodiments, the pre-treatment via operation 340 of the epitaxial silicon layers 115a, 115b is performed in a first processing chamber and the deposition of gases via operation 350 on the epitaxial silicon layers 115a, 115b is performed in a second processing chamber. In yet other embodiments, the pre-treatment of the epitaxial silicon layers 115a, 115b and the deposition of the epitaxial silicon layers 115a, 115b are performed in one chamber.

FIG. 4 is a schematic side cross-sectional view of an exemplary process chamber 400 that may be used to practice various embodiments of the deposition process discussed in this disclosure. The chamber 400 may be utilized for performing chemical vapor deposition such as epitaxial deposition processes, although the chamber 400 may be utilized for etching or other processes. The chamber 400 includes a housing structure 402 made of a process resistant material. Such as aluminum or stainless steel. The housing structure 402 encloses various functioning elements of the process chamber 400, such as a quartz chamber 404, which includes an upper chamber 406, and a lower chamber 408, in which a processing volume 410 is contained. A substrate support 412 made of a ceramic material or a graphite material coated with a silicon material. Such as silicon carbide, is adapted to receive a substrate 414 within the quartz chamber 404. The substrate support 412 includes a lift mechanism 472 and a rotation mechanism 474 coupled to the substrate support assembly 464. The lift mechanism 472 can be utilized for moving the substrate support 412 along the central axis “A”. The rotation mechanism 474 can be utilized for rotating the substrate support 412 about the central axis “A”. Reactive species from precursor reactant materials are applied to a processing surface 416 of the substrate 414, and byproducts may be subsequently removed from the processing surface 416.

Heating of the substrate 414 and/or the processing volume 410 is provided by an energy source, which may be a radiant Source or a thermal source. Radiant source may include UV, IR, and visible frequency lamps, lasers, and LEDs, or any combinations thereof. Thermal sources may be lasers, LEDs, and filament lamps, or combinations thereof. In one embodiment shown in FIG. 4, the energy source is a radiant source using lamps, such as upper lamp modules 418A and/or lower lamp modules 418B. In one embodiment, as shown in FIG. 4, the lamp modules 418A, 418B are installed horizontally. In one example, the upper lamp modules 418A and lower lamp modules 418B are infrared lamps. Radiation from lamp modules 418A and 418B travels through an upper quartz window 420 of upper chamber 406, and through a lower quartz window 422 of lower chamber 408. Cooling gases for upper chamber 406, if needed, enter through an inlet 424 and exit through an outlet 426.

Reactive species are provided to the quartz chamber 404 by a gas distribution assembly 428, and processing byproducts are removed from processing volume 410 by an exhaust assembly 430, which is typically in communication with a vacuum source (not shown). Precursor reactant materials, as well as diluent, purge and vent gases for the chamber 400, may enter through a gas distribution assembly 428 and exit through the exhaust assembly 430. The process chamber 400 includes multiple liners 432A-432G. The liners 432A-432G shield the processing volume 410 from metallic walls 434 that surround the processing volume 410. In one embodiment, the liners 432A-432G comprise a process kit that covers all metallic components that may be in communication with or otherwise exposed to the processing volume 410.

A lower liner 432A is disposed in the lower chamber 408. An upper liner 432B is disposed at least partially in the lower chamber 408 and is adjacent the lower liner 432A. An exhaust insert liner assembly 432C is disposed adjacent the upper liner 432B. In FIG. 4, an exhaust insert liner 432D is disposed adjacent the exhaust insert liner assembly 432C and may replace a portion of the upper liner 432B to facilitate installation. An injector liner 432E is shown on the side of the processing volume 410 opposite the exhaust insert liner assembly 432C and the exhaust liner 432D. The injector liner 432E is configured as a manifold to provide one or more fluids, such as a gas or a plasma of a gas, to the processing volume 410. The one or more fluids are provided to the injector liner 432E by an inject insert liner assembly 432F. A baffle liner 432G is coupled to the inject insert liner assembly 432F. The baffle liner 432G is coupled to a first gas source 435A and a second gas source 435B and provides gases to the inject insert liner assembly 432F and to gas outlets 436A and 436B formed in the injector liner 432E.

In one embodiment, one or more gases are provided to the processing volume 410 from the first gas source 435A, the second gas source 435B, and the third gas source 435C through the baffle liner 432G, the inject insert liner assembly 432F and through the one or more gas outlets 436A and 436B formed in the injector liner 432E. The one or more gas outlets 436A and 436B formed in the injector liner 432E are coupled to outlets configured for an angled/laminar flow path 433A or 433B. As will be discussed in more detail below, one or more of the gas outlets 436A are angled differently with respect to an axis A′ that is in parallel to the substrate surface to tune the film uniformity across the substrate. The gas outlets 436A and 436B are configured to provide individual or multiple gas flows with varied parameters, such as velocity, density, or composition.

In one embodiment where multiple gas outlets 436A and 436B are adapted, the gas outlets 436A and 436B may be distributed along a portion of the circumference of the gas distribution assembly 428 (e.g., injector liner 432E) in a substantial linear arrangement to provide a gas flow that is wide enough to substantially cover the diameter of the substrate. For example, each of the gas outlets 436A and 436B may be arranged to the extent possible in at least one linear group to provide a gas flow generally corresponding to the diameter of the substrate. The gas(es) coming out of the gas outlets 436A are flowed along the flow path 433B which is generally at an angle with respect to an axis A′ (substantially normal to a longitudinal axis A′ of the chamber 400), and mixed with the gas(es) coming out of the gas outlets 436B. The gases or gas mixture flowing along flow paths 433A, 433B across the entire surface of the substrate and into a plenum 437 in the exhaust liner 432D along an exhaust flow path 433C. The plenum 437 is coupled to an exhaust or vacuum pump (not shown). In one embodiment, the plenum 437 is coupled to a manifold 439 that directs the exhaust flow path 433C in a direction that is substantially parallel to the longitudinal axis A′. At least the inject insert liner assembly 432F may be disposed through and partially supported by an inject cap 429.

FIG. 5 is a schematic view of a system 500 for processing substrates, according to one embodiment. The system 500 can be used to conduct the operations of the method 300 shown in FIG. 3. The system 500 includes a cluster tool 501. The cluster tool 501 of the system 500 includes one or more processing chambers 502, 503, 516, 518 (a plurality of processing chambers 502, 503, 516, 518 are shown) coupled to one or more transfer chambers 504 and 510.

A first transfer chamber 504 is coupled to one or more epitaxy chambers 502. The first transfer chamber 504 has a centrally disposed transfer robot 515 for transferring substrates between the epitaxy chambers 502, the etch chambers 503, and a plurality of pass-through stations 506. The first transfer chamber 504 is coupled via the pass through stations 506 to a second transfer chamber 510, which is coupled to a cleaning chamber 516 for cleaning the substrates and to an anneal chamber 518. The second transfer chamber 510 has a centrally disposed transfer robot 514 for transferring substrates between a set of load lock chambers 512 and the cleaning chamber 516. A factory interface 520 is connected to the second transfer chamber 510 by the load lock chambers 512. The factory interface 520 is coupled to one or more pods 530 on the opposite side of the load lock chambers 512. The pods 530 typically are front opening unified pods (FOUP) that are accessible from the clean room in which the cluster tool 501 is disposed.

In one embodiment of the operation, substrates may be first transferred to the cleaning chamber 516 in which the substrates are pre-cleaned. The substrates are then transferred to one or more etch chambers 503, in which the substrates are exposed to atomic hydrogen radicals to etch the substrates and remove nodules from the substrates, as described for operation 310. The substrates are then transferred to one or more processing chambers 502 to selectively grow an epitaxial layer on the substrates, as described for operation 340 and 350. The substrates may then transferred to the anneal chamber 518, in which the epitaxial layers formed on the substrates are annealed to an anneal temperature.

The first transfer chamber 504 and second transfer chamber 510 are held under vacuum during operations such that the transfer robots 514 and 515 transfers substrates under vacuum between all the processing chambers, the load lock chambers 512, and the pass through stations 506. Transferring the substrates under vacuum facilitates decreasing the chance of contamination, improving the quality of the deposited epitaxial films, and rendering optional a pre-cleaning process before repetition of the injecting of the pre-treatment gas and introduction of the deposition gases operations 140 and 150 are repeated. The present disclosure contemplates that one or more of the chambers shown in the system 500 may not be clustered into the cluster tool 501. For example, either or both of the etch chambers 503 and/or the anneal chamber 518 in the system 500 can be separate (not clustered) from the cluster tool 501 having the cleaning chamber 516 and the epitaxy chambers 502. Use of the cleaning chamber 516 is present when the substrate is brought back (from the separate etch chamber and the separate anneal chambers) for repeat of the epitaxy operation, unless the cluster tool 501 is capable of receiving a purged FOUP or a portable vacuum station to minimize contamination when the substrate is transferred out and into the cluster tool 501.

In the embodiment shown in FIG. 5, the cleaning chamber 516, the epitaxy chambers 502, the etch chambers 503, and the anneal chamber 518 are distinct from each other. In one embodiment, which can be combined with other embodiments, each processing chamber of the processing chambers 502 and 503 is a single processing chamber in which each of the operations 310, 320, 330, 340, 350, the repeating in operation 340, and the repeating in operation 350 are conducted.

The system 500 includes a non-transitory computer-readable medium 550 that is configured to control operations of the cluster tool 501. The non-transitory computer-readable medium 550 is coupled to the pods 530, the factory interface 520, the load lock chambers 512, the second transfer chamber 510, the transfer robot 514, the cleaning chamber 516, the epitaxy chambers 502, the first transfer chamber 504, the transfer robot 515, the etch chambers 503, and the anneal chamber 518 to control the operations thereof. The non-transitory computer-readable medium 550 includes instructions that, when executed, cause the cleaning chamber 516, the epitaxy chambers 502, the etch chambers 503, and the anneal chamber 518 to conduct the operations of the method 300. In one embodiment, which can be combined with other embodiments, the non-transitory computer-readable medium 550 is a controller that includes the instructions.

While the foregoing is directed to embodiments of the present disclosure, other and further embodiments of the disclosure may be devised without departing from the basic scope thereof, and the scope thereof is determined by the claims that follow.

1. A method of forming a semiconductor device comprising:
positioning a substrate into a processing chamber, the substrate having an exposed non-crystalline surface and an exposed crystalline surface;
heating the processing chamber to a temperature for deposition;
injecting a pre-treatment gas into the processing chamber, wherein the pre-treatment gas comprises a molecule configured to lower interfacial energy between the exposed non-crystalline surface and the exposed crystalline surface; and
injecting a deposition gas into the processing chamber to selectively grow an n-type doped epitaxial silicon layer on the exposed crystalline surface.

2. The method of claim 1, wherein the molecule is a group-V chloride.

3. The method of claim 2, wherein the molecule is selected from a group consisting of PCl₃, AsCl₃, and SbCl₃.

4. The method of claim 1, wherein the injecting a pre-treatment gas and the injecting a deposition gas at least partially overlap.

5. The method of claim 1, wherein the injecting a pre-treatment gas is completed prior to the injecting a deposition gas.

6. The method of claim 1, wherein the injecting a pre-treatment gas and the injecting a deposition gas are repeated sequentially a plurality of times.

7. The method of claim 1, further comprising exposing the substrate to a dry etchant to remove contaminants from a surface of the substrate.

8. The method of claim 1, wherein the exposed non-crystalline surface comprises a silicon oxide, a silicon nitride, a silicon carbonitride, a silicon oxycarbide, a silicon oxycarbonitride, or a combination thereof.

9. The method of claim 1, wherein the dry etching comprises exposure of the substrate to H₂, NF₃, NH₃ and plasma by-products.

10. The method of claim 1, wherein the plurality of exposed silicon layers have <110> structure.

11. The method of claim 1, wherein the temperature for deposition is 400 degrees Celsius or higher.

12. The method of claim 1, wherein the injecting a pre-treatment gas is performed at a pressure within a range from about 1 torr to about 760 torr.

13. A method of forming a semiconductor device comprising:
positioning a substrate into a processing chamber, the substrate having a multi-material layer formed thereon, the multi-material layer comprising, a plurality of exposed dielectric surfaces on a plurality of Si₁₋ₓGeₓ layers and a plurality of exposed silicon layers;
heating the processing chamber to a temperature for deposition;
injecting a pre-treatment gas into the processing chamber, wherein the pre-treatment gas comprises a molecule configured to lower interfacial energy between the plurality of exposed dielectric surfaces and the plurality of exposed silicon layers; and
injecting a deposition gas into the processing chamber to selectively grow an n-type doped epitaxial silicon layer on the exposed silicon layers.

14. The method of claim 13, wherein the exposed dielectric surface comprises SiC_{y}N_{z} wherein y is greater than or equal to zero and z is greater than zero.

15. The method of claim 13, wherein the molecule is a group-V chloride.

16. The method of claim 15, wherein the molecule is selected from a group consisting of PCl₃, AsCl₃, and SbCl₃.

17. A method of forming a semiconductor device comprising:
positioning a substrate into a cleaning chamber, the substrate having a multi-material layer formed thereon, the multi-material layer comprising a plurality of dielectric surfaces disposed on outer surfaces of a plurality of Si₁₋ₓGeₓ layers and a plurality of silicon layers, the plurality of Si₁₋ₓGeₓ layers arranged in an alternating pattern with the plurality of silicon layers;
exposing the substrate to a dry etchant to remove contaminants from a surface of the substrate;
positioning the substrate into a processing chamber;
heating the processing chamber to a temperature for deposition;
injecting a pre-treatment gas into the processing chamber, wherein the pre-treatment gas comprises a molecule configured to lower interfacial energy between the dielectric surface and the silicon surface; and
injecting a deposition gas into the processing chamber to selectively grow an n-type doped epitaxial silicon layer on the exposed silicon surface.

18. The method of claim 17, wherein the molecule is a group-V chloride.

19. The method of claim 17, wherein the injecting a pre-treatment gas and the injecting a deposition gas are repeated sequentially a plurality of times.

20. The method of claim 17, wherein the exposed dielectric surface comprises a silicon oxide, a silicon nitride, a silicon carbonitride, a silicon oxycarbide, a silicon oxycarbonitride, or a combination thereof.
